(19) United States
(12) Patent Application Publication
(10) Pub. No.: US 2025/0385444 A1
(43) Pub. Date: Dec. 18, 2025

(54) CABLE CONNECTING METHOD, PRODUCTION METHOD OF CONNECTING MEMBER, AND THERMAL PROCESSING APPARATUS

(71) Applicant: Tokyo Electron Limited, Tokyo (JP)

(72) Inventors: Toshiki KOBAYASHI, Kanagawa (JP); Makoto NAKAJIMA, Iwate (JP)

(21) Appl. No.: 19/214,445

(22) Filed: May 21, 2025

(30) Foreign Application Priority Data
Jun. 12, 2024 (JP) 2024-095046

(51) Int. Cl. H01R 4/02; H01R 43/02; H05B 3/00

(52) U.S. Cl. CPC H01R 4/023; H01R 43/02; H05B 3/0019; H05B 3/0047; H05B 2203/016

(57) ABSTRACT

A cable connecting method of connecting a heater and a conductive cable configured to supply a power to the heater, the heater being provided in a thermal processing apparatus and including a heater body and a terminal conductive to the heater body, includes providing a connecting member configured to connect the terminal and the conductive cable; joining a first portion of the connecting member and the terminal through welding, the first portion being formed of a material the same as a material of the terminal; and linking a second portion of the connecting member and the conductive cable through caulking, the second portion being formed of a material different from the material of the first portion.

### CROSS-REFERENCE TO RELATED APPLICATIONS

This application is based upon and claims priority to Japanese Patent Application No. 2024-095046, filed on Jun. 12, 2024, the entire contents of which are incorporated herein by reference.

### BACKGROUND

### 1. Field of the Invention

The present disclosure relates to a cable connecting method, a production method of a connecting member, and a thermal processing apparatus.

### 2. Description of the Related Art

A thermal processing apparatus configured to process a plurality of substrates includes a temperature-controlled furnace that covers a process chamber outside the process chamber. A power corresponding to a target temperature is supplied via conductive cables to a plurality of heaters provided in the temperature-controlled furnace, thereby heating the substrates in the process chamber. In this type of a thermal processing apparatus, a terminal of each heater and a terminal of each conductive cable are connected through bolting. Therefore, during the operation of the thermal processing apparatus, some tasks, such as fastening bolts or the like, are performed on a regular basis.

Japanese Laid-Open Patent Application Publication No. 1993-291159 discloses a connecting apparatus configured to connect a terminal (power terminal) of a heater and a conductive cable (power supply cable). This connecting apparatus prevents the conductive cable from slipping out of the connecting apparatus by sandwiching and holding the conductive cable.

### SUMMARY

An aspect of the present disclosure provides a cable connecting method of connecting a heater and a conductive cable configured to supply a power to the heater, the heater being provided in a thermal processing apparatus and including a heater body and a terminal conductive to the heater body. The cable connecting method includes: (A) providing a connecting member configured to connect the terminal and the conductive cable; (B) joining a first portion of the connecting member and the terminal through welding, the first portion being formed of a material the same as a material of the terminal; and (C) linking a second portion of the connecting member and the conductive cable through caulking, the second portion being formed of a material different from the material of the first portion.

### BRIEF DESCRIPTION OF THE DRAWINGS

FIG. 1 is a diagram schematically illustrating an overall configuration of a thermal processing apparatus according to an embodiment of the present disclosure;

FIG. 2 is a perspective diagram illustrating the exterior of a temperature-controlled furnace of the thermal processing apparatus;

FIG. 3A is an enlarged perspective diagram illustrating connection between a busbar, a connecting member, and a conductive cable according to the embodiment;

FIG. 3B is an enlarged perspective diagram illustrating connection between a busbar and a conductive cable according to a Reference Example;

FIG. 4 is an enlarged perspective diagram illustrating the connecting member;

FIG. 5 is a partial cross-sectional plan diagram schematically illustrating an arrangement of the conductive cable according to the embodiment;

FIG. 6 is a flowchart illustrating a production method of the connecting member;

FIG. 7A is a diagram illustrating friction welding of the production method;

FIG. 7B is a diagram illustrating a second precursor after sleeve processing;

FIG. 7C is a diagram illustrating a form of connection between the busbar, the connecting member, and the conductive cable;

FIG. 8 is a flowchart illustrating a cable connecting method; and

FIG. 9 is a perspective diagram illustrating a temperature-controlled furnace according to a Modified Example.

### DETAILED DESCRIPTION OF THE DISCLOSURE

The present disclosure provides a technique that enables stable connection of a conductive cable, and reduction in cost.

Hereinafter, embodiments of the present disclosure will be described with reference to the drawings. In the drawings, the same components are denoted by the same reference symbols, and thus duplicate description thereof may be omitted.

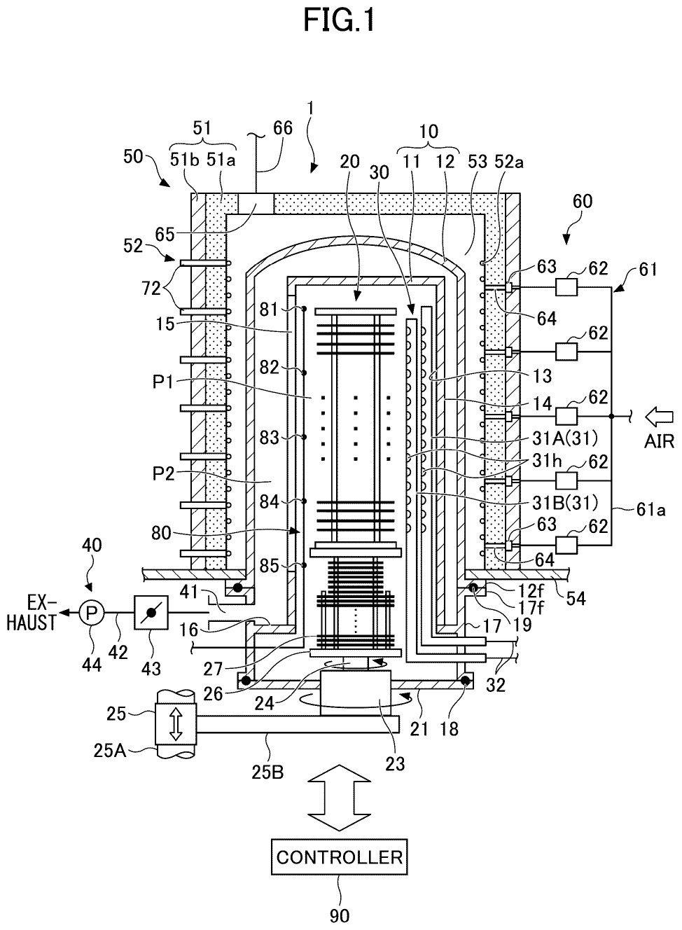

As illustrated in FIG. 1, a thermal processing apparatus 1 according to the present disclosure is a vertical film-forming apparatus configured to hold a plurality of substrates W side by side in the vertical direction, and form a desired film over the surfaces of the substrates W through atomic layer deposition (ALD), chemical vapor deposition (CVD), thermal oxidation, or the like. No particular limitation is imposed on the substrates W over which films are to be formed. The substrates W are, for example, silicon wafers, semiconductor substrates, such as compound semiconductor wafers or the like, or glass substrates.

The thermal processing apparatus 1 includes: a process chamber 10 configured to house the substrates W and perform film formation; a gas supply 30 configured to supply gas into the process chamber 10; a gas exhauster 40 configured to exhaust the internal gas from the process chamber 10; and a temperature-controlled furnace 50 disposed around the process chamber 10. Also, the thermal processing apparatus 1 includes a controller 90 configured to control the components of a system including the thermal processing apparatus 1.

The process chamber 10 is formed in a hollow cylindrical shape, and is disposed such that the axis of the process chamber 10 is along the vertical direction (upward-downward direction). Also, the process chamber 10 has a double-cylinder structure including an inner cylinder 11 and an outer cylinder 12 housing the inner cylinder 11. The inner cylinder 11 and the outer cylinder 12 are formed of a heat-resistant material, such as quartz or the like, and are disposed coaxially. The structure of the process chamber 10 is not limited to the double-cylinder structure, and may be a single-cylinder structure or a multi-cylinder structure including three or more cylinders.

The inner cylinder 11 has an open lower end and a ceiling wall at the upper end. The inner cylinder 11 has an inner diameter larger than the diameter of the substrates W. The interior of the inner cylinder 11 serves as a processing space P1 in which gas is supplied to the housed substrates W for film formation. At an appropriate circumferential position of the inner cylinder 11, an opening 15 through which gas is caused to flow out from the processing space P1 to a gas flow space P2 between the inner cylinder 11 and the outer cylinder 12 is provided. The opening 15 may be formed, for example, in the ceiling wall of the inner cylinder 11.

The inner cylinder 11 includes a housing 13 configured to house a gas supply nozzle 31 of the gas supply 30, and the housing 13 is located at a circumferential position opposite to the opening 15. As an example, the housing 13 is provided inward of a projection 14, i.e., a radially outwardly projecting part of the side wall of the inner cylinder 11.

The outer cylinder 12 has an inner diameter larger than the diameter of the inner cylinder 11, and covers the inner cylinder 11 in a non-contact manner. The gas flow space P2 formed inward of the outer cylinder 12 is continuous upward and laterally of the inner cylinder 11, and causes the gas moved from the opening 15 to flow vertically downward.

The lower end of the process chamber 10 is supported by a hollow cylindrical manifold 17 formed of stainless steel. The manifold 17 has a manifold-side flange 17f at the upper end. The manifold-side flange 17f fixes in place and supports an outer cylinder-side flange 12f formed at the lower end of the outer cylinder 12. A seal member 19 configured to airtightly seal the outer cylinder 12 and the manifold 17 is provided between the outer cylinder-side flange 12f and the manifold-side flange 17f. The manifold 17 includes an annular support plate 16 at the upper inner wall. The support plate 16 projects radially inward of the inner wall, and fixes in place and supports the lower end of the inner cylinder 11.

A cover 21 is disposed at the lower end opening of the manifold 17. The cover 21 is configured to be movable in the horizontal and vertical directions by an opening and closing mechanism (not shown) to open and close the lower end opening of the manifold 17 (see FIG. 1). The lower end of the manifold 17 includes a seal member 18 configured to airtightly close the lower end opening of the manifold 17 by being closed by the cover 21. After a wafer boat 20 is housed in the interior of the process chamber 10 and the manifold 17, the interior of the process chamber 10 and the manifold 17 is closed by the cover 21.

The wafer boat 20 is a substrate holder configured to hold the plurality of substrates W. The longitudinal direction of the wafer boat 20 is along the vertical direction. The wafer boat 20 holds the outer peripheral portions of the substrates W by a plurality of plates (not shown). In a state in which the substrates W are held by the wafer boat 20, the substrates W are arranged at constant intervals along the vertical direction, and are supported in the horizontal direction.

Further, the thermal processing apparatus 1 includes a rotating member 23 configured to rotatably support the wafer boat 20, and a raising and lowering member 25 configured to raise and lower the wafer boat 20 via the rotating member 23.

The rotating member 23 includes a rotation drive source (not shown), a rotating shaft 24 to be rotated by the rotation drive source, and a rotating plate 26 connected to the upper end of the rotating shaft 24. The wafer boat 20 is provided over the upper surface of the rotating plate 26 via a heat-insulating structure 27. The rotating member 23 rotates the rotating shaft 24 and the rotating plate 26, thereby rotating the heat-insulating structure 27 and the wafer boat 20 about the vertical axis.

The raising and lowering member 25 includes a column 25A extending in the vertical direction, an arm 25B configured to be raised and lowered relative to the column 25A, and a raising and lowering driver (not shown) configured to raise and lower the arm 25B. The arm 25B extends in the horizontal direction, and supports members (the wafer boat 20, the rotating plate 26, and the heat-insulating structure 27) above the rotating member 23 at the extended end portion. The thermal processing apparatus 1 raises and lowers the arm 25B of the raising and lowering member 25, thereby integrally raising and lowering members as a single unit that are above the cover 21, the rotating member 23, and the rotating shaft 24, and inserting and removing the wafer boat 20 relative to the process chamber 10.

For supplying gas to the substrates W disposed in the processing space P1, the gas supply 30 includes one or more gas supply nozzles 31. Examples of the gas supplied by the gas supply 30 include a raw material gas for deposition of a precursor over the substrates W, a reaction gas reactive with the precursor, a purge gas used for purging the processing space P1, and the like.

In the embodiment, the gas supply 30 includes two gas supply nozzles 31 (a first gas supply nozzle 31A and a second gas supply nozzle 31B). The first gas supply nozzle 31A is a nozzle configured to supply the raw material gas and the purge gas into the process chamber 10. The second gas supply nozzle 31B is a nozzle configured to supply the reaction gas into the process chamber 10. The gas supply 30 is not limited to this configuration, and may include, for example, the individual gas supply nozzles 31 for the raw material gas, the reaction gas, and the purge gas (i.e., three or more gas supply nozzles 31). Conversely, the gas supply 30 may be configured to supply the raw material gas, the reaction gas, and the purge gas from the single gas supply nozzle 31.

The gas supply nozzles 31 (the first gas supply nozzle 31A and the second gas supply nozzle 31B) are injector tubes formed of quartz, and are fixed to the manifold 17. Also, the gas supply nozzles 31 extend in the inner cylinder 11 in the vertical direction, and are bent in an L shape at the lower end to penetrate through the manifold 17 between the interior and the exterior. The gas supply nozzles 31 each include a plurality of gas holes 31h in the inner cylinder 11 at constant intervals in the vertical direction, and discharge gas from the gas holes 31h in the horizontal direction. The intervals between the gas holes 31h are set to be equal to, for example, the intervals between the substrates W supported by the wafer boat 20. The position of each of the gas holes 31h in the vertical direction is set to be between the substrates W next to each other in the vertical direction. The gas holes 31h formed in this manner can successfully supply the gas to the gap between the substrates W.

The gas supply 30 includes, outside the process chamber 10, a plurality of gas supply paths 32 connected to the first gas supply nozzle 31A and the second gas supply nozzle 31B. The gas supply path 32 connected to the first gas supply nozzle 31A is branched at a position partway along its length, and is connected to a raw material gas source and a purge gas source (not shown). The gas supply path 32 connected to the second gas supply nozzle 31B is connected to a reaction gas source (not shown). The gas supply paths 32 each include a flow rate regulator configured to regulate the gas flow rate, a valve configured to open and close the gas flow path in the path, and the like, at positions partway through each of the gas sources (the flow rate regulator and the valve are not shown).

The gas exhauster 40 is configured to exhaust the internal gas of the process chamber 10 to the exterior of the process chamber 10. The gas supplied by each of the gas supply nozzles 31 moves to the gas flow space P2 from the processing space P1 in the inner cylinder 11, and then is exhausted through a gas outlet 41. The gas outlet 41 is formed in an upper side wall of the manifold 17 and above the support plate 16. A gas exhaust path 42 of the gas exhauster 40 is connected to the gas outlet 41.

The gas exhauster 40 includes a pressure regulating valve 43 and a vacuum pump 44 in order from upstream to downstream of the gas exhaust path 42. The vacuum pump 44 is configured to generate a suction pressure by driving a suction driver (not shown), thereby suctioning the internal gas of the process chamber 10. As the pressure regulating valve 43, an automatic pressure control (APC) valve or the like is used. The APC valve is configured to regulate the internal pressure of the process chamber 10 by opening and closing the flow path of the gas exhaust path 42 or changing the degree of opening.

A temperature sensor 80 configured to detect the internal temperature of the process chamber 10 is provided in the interior of the process chamber 10 (e.g., the processing space P1 in the inner cylinder 11). The temperature sensor 80 includes a plurality of (five in the embodiment) thermometers 81 to 85 at different positions in the vertical direction. As the thermometers 81 to 85, thermocouples, resistance temperature detectors, and the like can be used. The temperature sensor 80 transmits, to the controller 90, the temperatures detected by the thermometers 81 to 85.

The temperature-controlled furnace 50 covers the overall process chamber 10, and is configured to heat and cool the substrates W housed in the process chamber 10 from the exterior of the process chamber 10. Specifically, the temperature-controlled furnace 50 includes a hollow cylindrical housing 51 having a ceiling, and a plurality of heaters 52 provided inside the housing 51.

The housing 51 is formed to be larger than the process chamber 10. The center axis of the housing 51 is set at a position substantially the same as the center axis of the process chamber 10. For example, the housing 51 is attached to the upper surface of a base plate 54, to which the outer cylinder-side flange 12f is fixed. The housing 51 is provided to be apart from the outer circumferential surface of the process chamber 10, thereby forming a temperature-controlled space 53 between the outer circumferential surface of the process chamber 10 and the inner circumferential surface of the housing 51. The temperature-controlled space 53 is provided to be continuous laterally and upward of the process chamber 10.

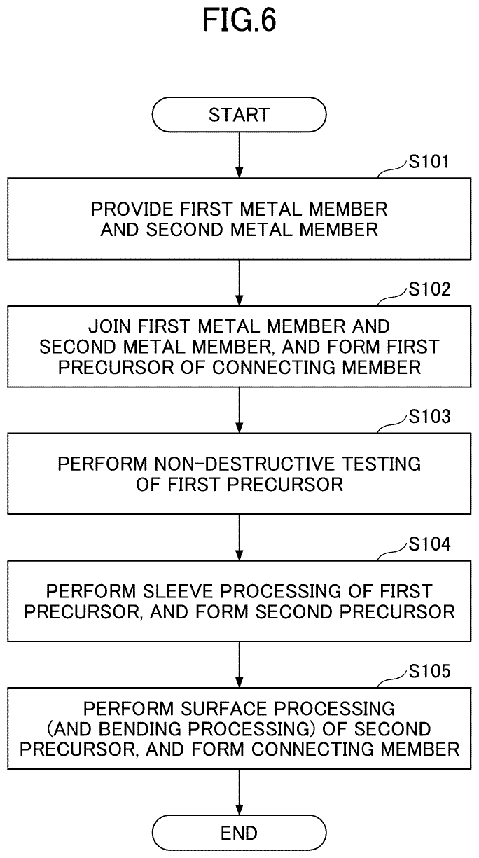

The housing 51 includes a heat-insulating portion 51a including a ceiling and covering the overall process chamber 10, and a reinforcing portion 51b configured to reinforce the heat-insulating portion 51a on the outer circumference side of the heat-insulating portion 51a. That is, the side wall of the housing 51 has a stacked structure of the heat-insulating portion 51a and the reinforcing portion 51b. The heat-insulating portion 51a is formed of silica, alumina, or the like, which is a main component. The heat-insulating portion 51a is configured to suppress heat transfer in the heat-insulating portion 51a. The reinforcing portion 51b is formed of a metal, such as stainless steel or the like. Also, for suppressing thermal effects of heat on the exterior of the temperature-controlled furnace 50, the reinforcing portion 51b includes a water-cooling jacket 55 (see FIG. 5) near the outer circumferential surface.

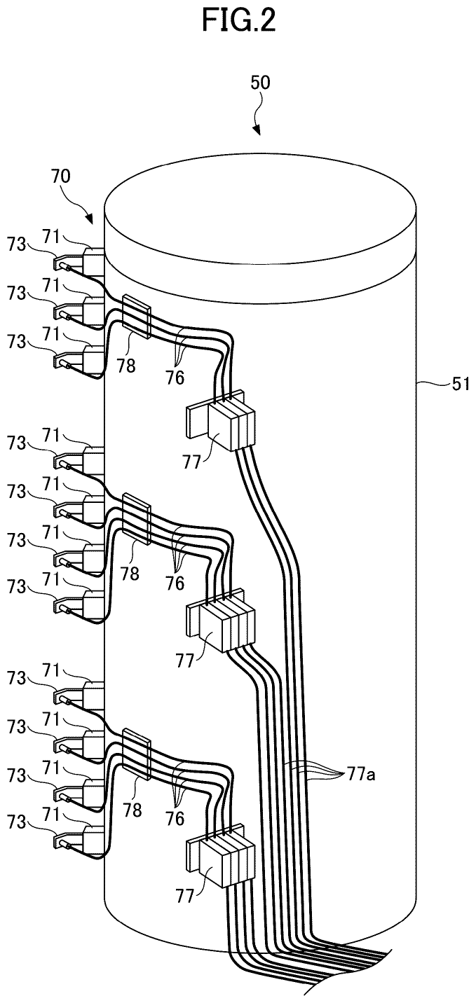

The plurality of heaters 52 of the temperature-controlled furnace 50 are arranged in the vertical direction, and are configured to heat the substrates W entirely laterally of the process chamber 10. The temperature-controlled furnace 50 divides a group of the heaters 52 into a plurality of (e.g., three) zones along the vertical direction. The heaters 52 are connected to a temperature control driver via conductive cables 76 (see FIG. 2) described below. The temperature control driver is connected to the controller 90. The temperature control driver is configured to supply a power, adjusted under the control of the controller 90, to the heaters 52, thereby heating the heaters 52. Thus, the thermal processing apparatus 1 can adjust the temperature of the process chamber 10 independently for each of the divided zones.

The heaters 52 each include a heater body 52a, circulating in the heat-insulating portion 51a, and a busbar 72, which is a terminal connected to the heater body 52a (see FIG. 5). For example, as the heater body 52a, a heater wire configured to heat the process chamber 10 by irradiation with infrared rays can be used. The configuration of the busbar 72 connected to the heater body 52a will be described below in detail.

Further, for cooling the process chamber 10 at the time of or after film formation, the temperature-controlled furnace 50 includes a cooler 60 configured to circulate a cooling gas, such as air or the like, in the temperature-controlled space 53. The cooler 60 includes: an external supply path 61 and a flow rate regulator 62 that are provided outside the temperature-controlled furnace 50; a supply flow path 63 provided in the reinforcing portion 51b; and a plurality of supply holes 64 provided in the heat-insulating portion 51a.

The cooler 60 includes a gas exhaust hole 65 in the ceiling of the housing 51. The gas exhaust hole 65 is a hole through which air supplied into the temperature-controlled space 53 is exhausted. The gas exhaust hole 65 is connected to an external gas exhaust path 66 provided outside the housing 51.

In the above example, the thermal processing apparatus 1 is described as an apparatus configured to supply the raw material gas and the reaction gas as the process gases, thereby forming a desired film over the surface of the substrates W. However, the thermal processing apparatus 1 is not limited to such a film-forming apparatus. For example, the thermal processing apparatus 1 may be applied as an apparatus configured to etch a film over the surface of the substrates W, or an apparatus configured to modify or clean the surface of the substrates W. The thermal processing apparatus 1 may be configured to generate a plasma in the process chamber 10.

As the controller 90 of the thermal processing apparatus 1, it is possible to use a computer including a processor, a memory, an input/output interface, a communication interface, and the like. The processor is one of or a combination of one or more of a CPU (Central Processing Unit), a GPU (Graphics Processing Unit), an ASIC (Application Specific Integrated Circuit), an FPGA (Field-Programmable Gate Array), a circuit formed of a plurality of discrete semiconductors, and the like. The memory includes a main storage formed of a semiconductor memory or the like, and an auxiliary storage formed of a disk, a semiconductor memory (flash memory), or the like. The memory may be configured of an appropriate combination of a volatile memory and a non-volatile memory (e.g., a compact disc, a DVD (Digital Versatile Disc), a hard disk, a flash memory, or the like).

The memory stores programs causing the thermal processing apparatus 1 to operate, and recipes, such as, for example, process conditions for thermal processing. The processor controls the components of the thermal processing apparatus 1 by reading out a program from a memory and executing the program. In other words, the controller 90 of the present disclosure is an electronic circuit including a CPU, a GPU, an ASIC, an FPGA, or the like, and executes various controls described in the present specification by executing instruction codes stored in the memory or by being designed as circuits for specific applications. The controller may be configured by a host computer or a plurality of client computers configured to perform information communication via a network. The thermal processing apparatus 1 is not limited to a configuration in which the controller 90 directly controls respective components. The thermal processing apparatus 1 may have a configuration in which an appropriate component (e.g., the temperature-controlled furnace 50) is provided with a dedicated controller, and a control command of the controller 90 is transmitted to the controller, so that the controller controls respective components.

### <Configuration of Power Supply Connecting Structure 70>

For supplying a power to each of the plurality of heaters 52 provided in the temperature-controlled furnace 50, the thermal processing apparatus 1 described above includes a plurality of power supply connecting structures 70 for the respective heaters 52 as illustrated in FIG. 2. Next, the power supply connecting structures 70 will be described in detail.

For realizing stable connection between the heaters 52 and the conductive cables 76, the power supply connecting structures 70 each include a retainer 71, a busbar 72 of the heater 52, and a connecting member 73.

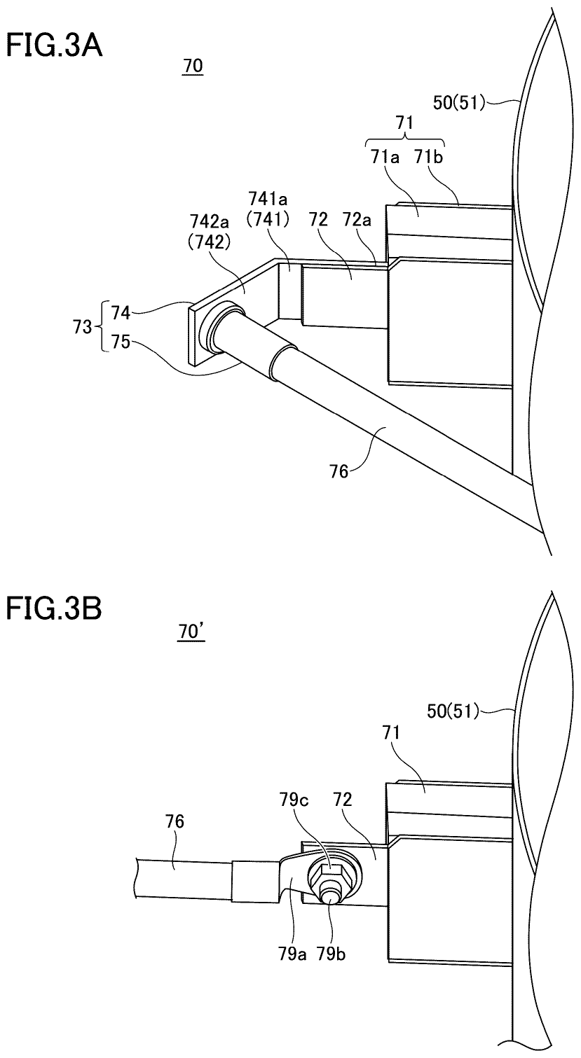

A plurality of the retainers 71 are arranged side by side in the vertical direction of the housing 51, corresponding to the plurality of heaters 52 of the temperature-controlled furnace 50. As illustrated in FIG. 3A, the retainers 71 are formed in a substantially rectangular parallelepiped shape, and fix and retain the busbars 72 of the heaters 52. The retainers 71 each include a contact body 71a configured to directly retain the busbar 72, and a pair of retaining plates 71b disposed over the outer surfaces of the contact body 71a.

The contact body 71a is formed of an insulating material, such as ceramics, a resin material, or the like. The contact body 71a can be divided into two at an intermediate position in the horizontal direction. The busbar 72 is sandwiched and retained between the divided two members. The busbar 72 to be held by the contact body 71a is formed in a plate shape long in the radial direction of the temperature-controlled furnace 50, and penetrates through the temperature-controlled furnace 50 between the exterior and the interior. The busbar 72 projects, by a predetermined length, from the projecting end surface of the contact body 71a.

The pair of retaining plates 71b are connected to the outer circumferential surface of the reinforcing portion 51b of the housing 51, and project radially outwardly (in the normal direction of the reinforcing portion 51b) from the reinforcing portion 51b. The pair of retaining plates 71b sandwich the two members of the contact body 71a, thereby reinforcing the retention of the busbar 72 by the contact body 71a.

The connecting member 73 is a terminal member configured to achieve electrical connection between the busbar 72, projecting from the retainer 71, and the conductive cable 76. The connecting member 73 according to the embodiment can firmly connect the busbar 72 and the conductive cable 76 without bolting as in the related art.

For ease of understanding of the power supply connecting structure 70 (the connecting member 73) according to the embodiment, first, a power supply connecting structure 70′ according to a Reference Example will be described with reference to FIG. 3B. The power supply connecting structure 70′ is a conventional structure in which the busbar 72 and the conductive cable 76 are connected through bolting.

The conductive cable 76 of the power supply connecting structure 70′ includes a connector 79a for bolting with the busbar 72. The connector 79a is formed, for example, in an annular shape having a fastening hole into which a bolt 79b can be inserted. The connector 79a is mounted over a covering member covering a core wire of the conductive cable 76, and is electrically connected to the internal core wire.

Also, the busbar 72 includes a fastening hole overlapping with the fastening hole of the connector 79a. The bolt 79b is inserted through these fastening holes, and an exposed external thread is screwed by a nut 79c. For suppressing release of the conductive cable 76, the nut 79c is fastened to the bolt 79b with a sufficiently high torque. Thus, the busbar 72 and the connector 79a are connected through bolting.

However, the power supply connecting structure 70′ as described above may have risks, such as, for example, contact failure at the initial stage of installation, and reduction in the fastening force due to thermal effects of heat or vibration during operation. For example, if contact failure occurs at the initial stage of installation, there is an increased risk of burnout of the thermal processing apparatus 1. For example, for preventing the fastening force from weakening during operation, the bolts need to be fastened on a regular basis. In particular, the temperature-controlled furnace 50 includes the plurality of the heaters 52 in the vertical direction as described above, and thus fastening the bolts between the heaters 52 and the conductive cables 76 requires a significant amount of labor.

### <Configuration of Connecting Member 73>

For avoiding the inconvenience caused by fastening the bolts as in the power supply connecting structure 70′ of the Reference Example, the power supply connecting structure 70 according to the embodiment connects the busbar 72 and the conductive cable 76 via the connecting member 73, as illustrated in FIG. 3A. Specifically, the connecting member 73 includes a plate 74, which is a first portion, and a sleeve 75, which is a second portion. The plate 74 and the sleeve 75 are firmly joined together, and can be handled integrally as a single unit.

The plate 74 has a rectangular flat plate having a substantially constant plate thickness. The thickness of the plate 74 is preferably set to have rigidity enough to avoid plastic deformation even if the plate 74 receives the weight of the conductive cable 76 or the like. Also, the plate 74 is formed to have a width in the vertical direction that is the same as the width of the busbar 72.

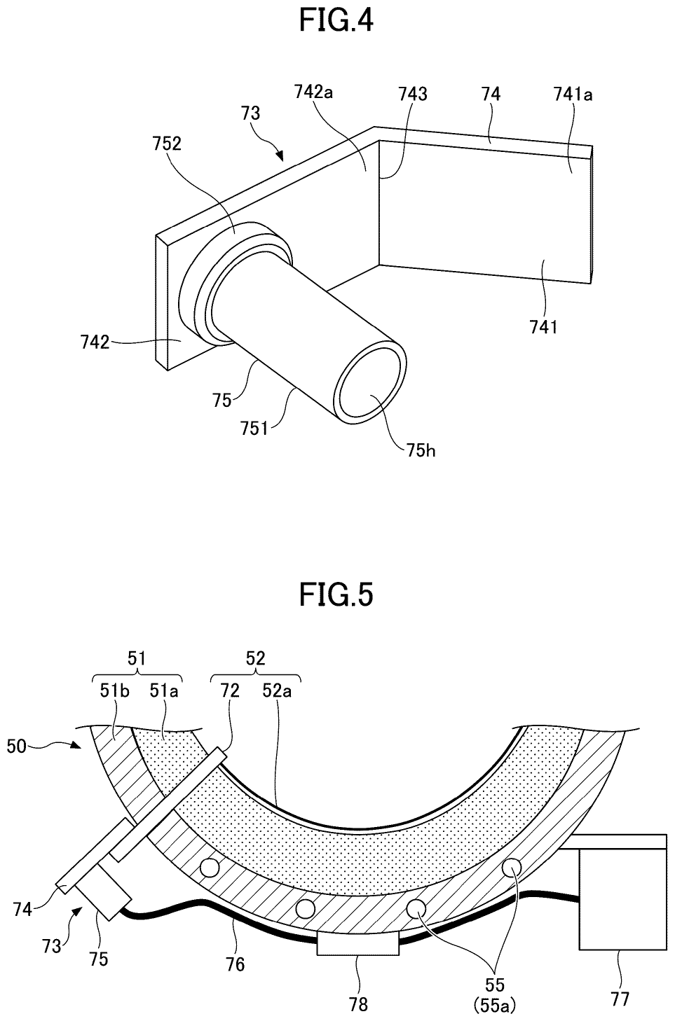

As illustrated in FIG. 4, the plate 74 includes a first region 741 to be joined to the busbar 72, and a second region 742 to which the sleeve 75 is linked. However, the first region 741 and the second region 742 are distinguished for the sake of convenience of description, and both regions are continuous with each other by a single plate.

Further, the plate 74 includes a bent portion 743 between the first region 741 and the second region 742 (at a position partway in the longitudinal direction). The bent portion 743 is a processed portion for causing the conductive cable 76 linked to the sleeve 75 to extend in a direction along the housing 51 of the temperature-controlled furnace 50. The connecting member 73 may be configured not to include the bent portion 743.

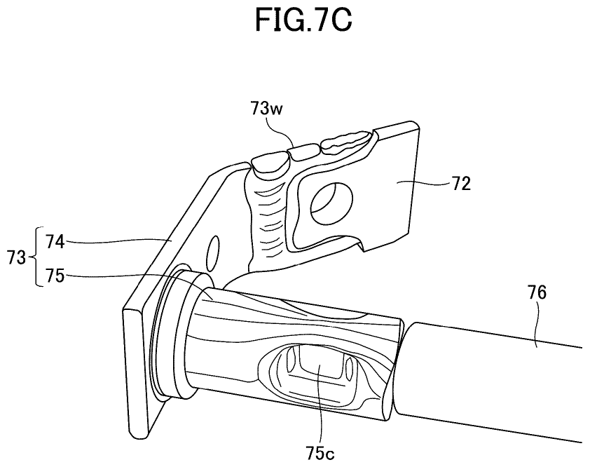

The first region 741 extends longer than a part of the busbar 72 extending from the retainer 71. The first region 741 of the connecting member 73 is joined to the busbar 72 through welding. Specifically, one surface 741a of the first region 741 and the other surface 72a of the busbar 72, facing each other, are welded. Welding performed at the gap (or a surrounding region thereof) between the one surface 741a and the other surface 72a forms a welded portion 73w (see FIG. 7C) at which the connecting member 73 and the busbar 72 adhere to each other. By performing welding in a state in which the one surface 741a and the other surface 72a are in plane-contact with each other, the welded portion 73w achieves a strong joint force.

In particular, the plate 74 of the connecting member 73 according to the embodiment is formed of a material the same as a material of the busbar 72. Examples of the material of the busbar 72 include iron (Fe), chromium (Cr), aluminum (Al), tungsten (W), cobalt (Co), nickel (Ni), and other metals, alloys containing any one of these as a main component, alloys of combinations of these, and the like. One example of the material of the busbar 72 is KANTHAL (registered trademark), which is an iron-chromium-aluminum alloy. The plate 74 is formed of the material the same as the material of the busbar 72. The term “same material” in the embodiment refers to a material in which a material used as a main component is the same. For example, materials in which the main component is the same and additives or the like other than the main component are different can be regarded as the same materials.

The second region 742 extends from one side of the first region 741 via the bent portion 743. The second region 742 retains the sleeve 75 at one surface 742a. In other words, the second region 742 functions to maintain an appropriate separation distance between the sleeve 75 and the busbar 72.

The sleeve 75 projects in a direction orthogonal to the one surface 742a of the second region 742, and retains the conductive cable 76. The sleeve 75 includes a cylinder body 751 formed to be thicker than the conductive cable 76, and an annular base 752 joined to the plate 74 at the base end side of the cylinder body 751. The sleeve 75 includes a hole 75h extending along the axial direction of the sleeve 75.

The sleeve 75 is linked to the conductive cable 76 through caulking of the cylinder body 751 in a state in which the core wire of the conductive cable 76 is inserted into the hole 75h, thereby forming a caulked portion 75c (see FIG. 7C). The hole 75h is preferably provided only within the cylinder body 751 in the axial direction of the sleeve 75. This configuration can ensure a sufficient joint region between the plate 74 and the base 752. However, the hole 75h may be formed to penetrate through the sleeve 75 and the plate 74.

The cylinder body 751 is formed to have a length appropriate for caulking of the cylinder body 751 and a substantially constant thickness along the axial direction. The thickness of the cylinder body 751 may be designed such that the cylinder body 751 is deformed by an appropriate force and can maintain the deformed shape. In other words, the cylinder body 751 has plasticity higher than the plasticity of the plate 74. Further, the cylinder body 751 may be formed to be thicker than the conductive cable 76 such that the core wire of the conductive cable 76 and a covering member can be housed in the hole 75h. By housing the covering member, the connecting member 73 can prevent exposure of the core wire of the conductive cable 76 at the linked portion of the conductive cable 76.

The base 752 is formed to be thicker than the cylinder body 751. For example, the base 752 is formed when the sleeve 75 is processed after the plate 74 and the sleeve 75 are joined together, thereby realizing strong joint between the plate 74 and the sleeve 75.

The sleeve 75 according to the embodiment is formed of a material different from the material of the plate 74, and is joined to the plate 74 through friction welding. The term “different material” in the embodiment refers to a material in which a material used as the main component is different. For example, materials in which the main component is different and additives or the like other than the main component are the same can be regarded as the different materials. As a material of the sleeve 75, it is preferable to use a metal material having conductivity and high processability. Examples of the material of the sleeve 75 include copper (Cu), copper alloys, and the like.

The sleeve 75 configured as described above can be formed to conform to the JIS standard c2806 (Non-insulated crimp-type sleeves for copper conductors) with respect to the shape of the sleeve 75 in a state in which the sleeve 75 is joined to the plate 74. Therefore, the sleeve 75 and the conductive cable 76 can be linked together at an appropriate crimping force.

As illustrated in FIG. 2, the conductive cable 76 whose end is connected to the connecting member 73 is connected to a relay terminal 77 disposed at the outer circumferential surface of the temperature-controlled furnace 50. The relay terminal 77 is fixed at an appropriate position in height at the outer circumferential surface of the temperature-controlled furnace 50 via a fixing frame. The temperature-controlled furnace 50 includes a plurality of the relay terminals 77 along the vertical direction.

For example, the conductive cables 76 for each of the zones of the temperature-controlled furnace 50 are connected to each of the relay terminals 77. As the relay terminal 77, a spring-type terminal block can be used. Also, other cables 77a conductive to the conductive cables 76 are connected to the relay terminal 77. The other cables 77a are connected to the temperature control driver provided outside the temperature-controlled furnace 50. This configuration enables the temperature-controlled furnace 50 to supply a power to the connecting member 73 from the temperature control driver through the other cables 77a, the relay terminals 77, and the conductive cables 76, and further supply a power to the heater body 52a through the connecting members 73 and the busbars 72.

The conductive cables 76 between the connecting members 73 and the relay terminals 77 are arranged along the outer circumferential surface of the temperature-controlled furnace 50. Therefore, holders 78 configured to hold the conductive cables 76 are provided between the connecting members 73 and the relay terminals 77. For example, the holders 78 are fixed to the housing 51 of the temperature-controlled furnace 50, and hold the conductive cables 76 for each of the zones of the temperature-controlled furnace 50.

The conductive cables 76 arranged in the above-described manner are in proximity to the outer circumferential surface of the temperature-controlled furnace 50 (the reinforcing portion 51b), as illustrated in FIG. 5. As described above, flow paths 55a of a water-cooling jacket 55 are formed near the outer circumferential surface of the reinforcing portion 51b, and a coolant flows through the flow paths 55a. Therefore, even if the temperature increases due to heat transfer through the busbar 72 and the connecting member 73, the conductive cables 76 can be lowered in temperature at the outer circumferential surface of the temperature-controlled furnace 50. As a result, the temperature-controlled furnace 50 can suppress an increase in the temperature of the relay terminals 77 via the conductive cables 76.

### <Production Method of Connecting Member 73>

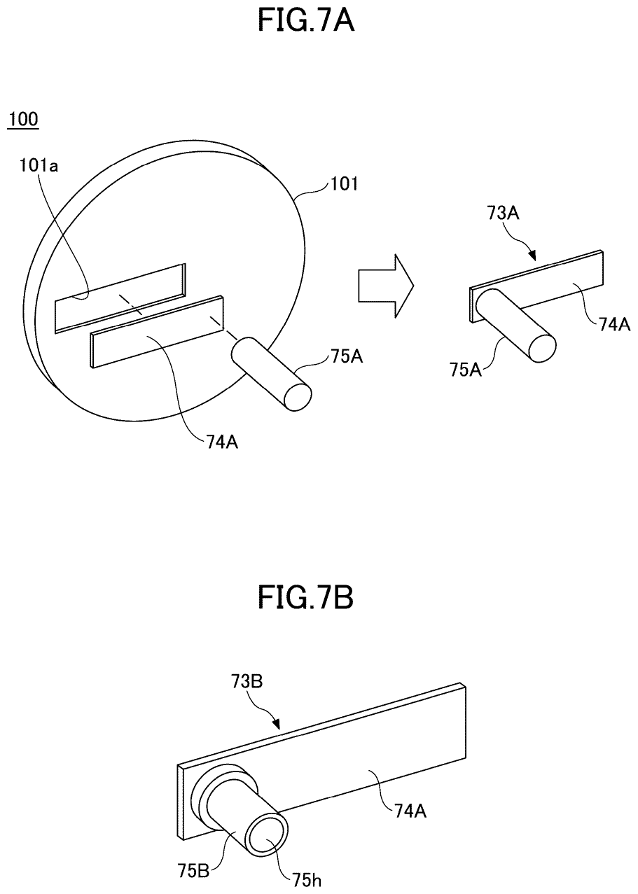

The thermal processing apparatus 1 according to the embodiment is basically configured as described above. Next, a production method of the connecting member 73 will be described with reference to FIG. 6 and FIGS. 7A to 7C.

In the production method of the connecting member 73, as illustrated in FIG. 6 and FIG. 7A, first, a first metal member 74A to be the plate 74 and a second metal member 75A to be the sleeve 75 are provided (step S101 in FIG. 6). The first metal member 74A is a flat-plate member formed of an appropriate material of the above-described materials of the plate 74. The first metal member 74A may be processed in advance to match the shape and size of the plate 74. Alternatively, a member larger than the plate 74 may be provided, and formed into the plate 74 through subsequent processing. The second metal member 75A is a solid cylindrical body formed of an appropriate material of the above-described materials of the sleeve 75. As the second metal member 75A, for example, a member having a diameter the same as the diameter of the base 752 of the sleeve 75 is provided.

In the production method, next, a first precursor 73A of the connecting member 73 is formed by joining the first metal member 74A and the second metal member 75A (step S102 in FIG. 6). The first metal member 74A and the second metal member 75A are joined together through friction welding as described above.

For the friction welding, a friction welding apparatus 100 as illustrated on the left side of FIG. 7A is used to join the first metal member 74A and the second metal member 75A together. For example, the friction welding apparatus 100 includes a holder 101 configured to hold the first metal member 74A, and another holder (not shown) configured to hold the second metal member 75A. The holder 101 includes a fixing hole 101a formed in the shape of the first metal member 74A. The first metal member 74A is set in the fixing hole 101a. After the setting, one end of the first metal member 74A is disposed at the center of the holder 101 having a disc shape. Then, while rotating the holder 101, the friction welding apparatus 100 contacts and compresses (presses) the second metal member 75A, held by the other holder, against the first metal member 74A located at the center of the holder 101. Thus, the first metal member 74A, rotating along with the holder 101, and the second metal member 75A are joined together by a friction force generated between the first metal member 74A and the second metal member 75A. That is, as illustrated on the right side of FIG. 7A, the first precursor 73A, in which the first metal member 74A and the second metal member 75A are firmly joined together, is formed.

Subsequently, in the production method, non-destructive testing is performed on the first precursor 73A formed through friction welding (step S103). For example, in the non-destructive testing, screening of the joined portion of the joined second metal member 75A is performed using an ultrasonic flaw detector (not shown). Through this non-destructive testing, joint failure between the first metal member 74A and the second metal member 75A can be found, and the first precursor 73A having joint failure can be eliminated at this stage.

Further, in the production method, sleeve processing is performed on the second metal member 75A of the first precursor 73A, thereby forming a second precursor 73B (step S104). For the sleeve processing, for example, the outer circumferential surface of the second metal member 75A can be cut using a cutting machine (not shown), thereby forming the cylinder body 751 (see FIG. 4) having a predetermined diameter. At this time, a region of the second metal member 75A to be joined to the first metal member 74A can be ensured by not cutting a part corresponding to the base 752. Further, in the sleeve processing, the hole 75h is bored in the axial center of the second metal member 75A with a cutting machine. Thus, as illustrated in FIG. 7B, the second precursor 73B includes a metal hollow cylindrical body 75B having a shape substantially the same as the shape of the sleeve 75 of the connecting member 73 to be used.

Finally, in the production method, surface processing, such as plating or the like, is performed on the metal hollow cylindrical body 75B of the obtained second precursor 73B to form the sleeve 75, and bending processing is performed on the first metal member 74A to form the bent portion 743, thereby obtaining the connecting member 73 as a final product (step S105). For the surface processing, for example, electrolytic nickel plating or tin plating is performed. Such plating can suppress corrosion of the sleeve 75. Also, in the production method, the target shape of the plate 74 may be obtained, for example, by cutting the first metal member 74A when steps S104 and S105 are performed.

The above-described production method can produce the connecting member 73 with high accuracy and at low cost. In particular, according to this production method, the first metal member 74A and the second metal member 75A, which are of different materials (heterogeneous metal materials), can be firmly joined together through friction welding. Also, in the production method, by performing the sleeve processing after joining between the first metal member 74A and the second metal member 75A, it is possible to eliminate inconveniences, such as joint failure, breakage, and the like, which are caused when a hollow cylindrical member is joined to a plate member.

The production method of the connecting member 73 is not limited to the above. For example, the non-destructive testing may be omitted after the formation of the first precursor 73A, or the non-destructive testing may be performed after the sleeve processing. Also, the production method may omit the surface processing, the bending processing, or both on the second precursor 73B. Therefore, the second precursor 73B may be used as the connecting member 73.

### <Cable Connecting Method>

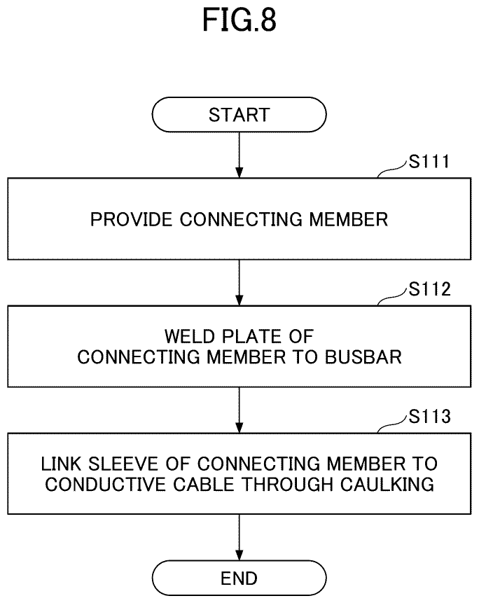

Next, a cable connecting method using the connecting member 73 will be described with reference to FIG. 8. In the cable connecting method, first, the connecting member 73 is provided to an operator who connects each conductive cable 76 to each heater 52 of the temperature-controlled furnace 50 of the thermal processing apparatus 1 (step S111). The busbar 72 of each heater 52 of the temperature-controlled furnace 50 is pre-configured in a state of projecting from the retainer 71. The connecting member 73 is formed by the above-described production method (steps S101 to S105), and provided in the number corresponding to the number of the busbars 72 of the heaters 52.

In the cable connecting method, the operator welds each connecting member 73 to each busbar 72 projecting from the outer circumferential surface of the temperature-controlled furnace 50 (step S112). For the welding between the busbar 72 and the connecting member 73, for example, TIG (Tungsten Inert Gas) welding is performed for joining the busbar 72 and the plate 74. By performing the TIG welding for welding between the busbar 72 and the plate 74 that are formed of the same material (homogeneous metal material), the busbar 72 and the plate 74 are smoothly stuck to each other, thereby forming the welded portion 73w at which the busbar 72 and the plate 74 can firmly adhere to each other. However, the welding method is not limited to this TIG welding, and a well-known welding method may be employed. The operator ends his/her task by joining the connecting member 73 to all of the busbars 72 provided along the vertical direction of the temperature-controlled furnace 50.

Then, the operator links the conductive cable 76 through caulking to the connecting member 73 fixed to the busbar 72 (step S113). At this time, the operator inserts the conductive cable 76 into the hole 75h of the sleeve 75 of the connecting member 73, and performs caulking from the exterior of the sleeve 75 with a dedicated tool, thereby forming the caulked portion 75c in the sleeve 75.

For example, as illustrated in FIG. 7C, the caulked portion 75c is formed in a recessed shape that is radially inwardly recessed from the surface of the sleeve 75. The sleeve 75 formed of a material different from the material of the plate 74 has plasticity higher than the plate 74. The caulked portion 75c enables firm linking of the conductive cable 76, while maintaining the shape of the caulked portion 75c and achieving electrical connection to the core wire of the conductive cable 76. The operator ends his/her task by linking the conductive cable 76 to all of the connecting members 73 provided along the vertical direction of the temperature-controlled furnace 50.

As described above, the cable connecting method according to the embodiment can readily and firmly connect the busbar 72 and the conductive cable 76 by use of the connecting member 73. The connecting member 73 has a simple configuration including the plate 74 and the sleeve 75, leading to reduction in cost. In the cable connecting method, the busbar 72 and the conductive cable 76 can be stably connected without bolting.

The cable connecting method, the production method of the connecting member 73, and the thermal processing apparatus 1 according to the embodiments are not limited to the above embodiments, and can have various Modified Examples. For example, the cable connecting method has been described using the procedure including, first, welding the busbar 72 and the connecting member 73, and, next, connecting the conductive cable 76 to the connecting member 73. However, this order may be reversed. That is, it is possible to employ a procedure including, first, linking the connecting member 73 and the conductive cable 76, and, next, welding the busbar 72 and the connecting member 73.

The shape of the first portion and/or the second portion of the connecting member 73 is not limited to a flat plate (the plate 74) and a hollow cylindrical shape (the sleeve 75), and can have various shapes that can be connected to the busbar 72 and the conductive cable 76. For example, the first portion may include an engaging portion, such as a hook or the like, that is engaged with the busbar 72, and the busbar 72 may include an engaged portion, such as a hole or the like, corresponding to the engaging portion. For example, the second portion may include a plurality of pieces that sandwich the conductive cable 76, and caulking may be performed by the pieces.

Further, the terminal of the heater 52 is not limited to the busbar 72 having a flat shape, and can have various shapes. For example, the terminal may have a rod shape, a hollow cylindrical shape, or the like, and the first portion of the connecting member 73 may be formed in a rod shape, a hollow cylindrical shape, or the like corresponding to the shape of the terminal, followed by welding.

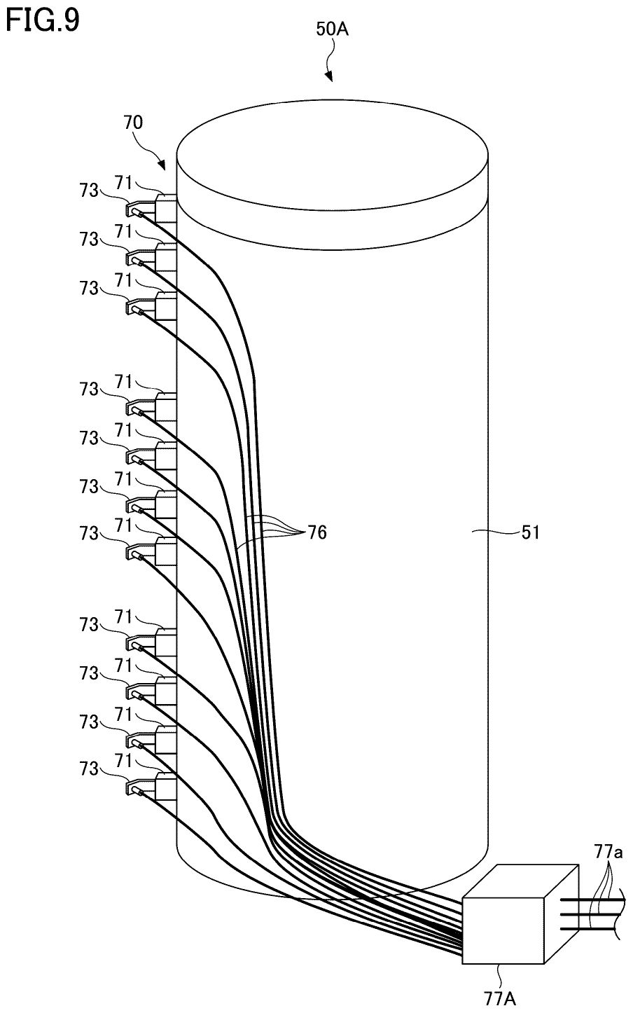

A temperature-controlled furnace 50A according to the Modified Example illustrated in FIG. 9 is different from the above-described temperature-controlled furnace 50 in that the relay terminal 77 is not disposed at the outer circumferential surface of the housing 51, and a relay terminal 77A is disposed at a position away from the housing 51 (e.g., on the floor). In this case, the conductive cable 76 linked to the connecting member 73 is extended and linked to the relay terminal 77A, and thus a power can be successfully supplied to the heater 52 via the relay terminal 77A. In particular, disposing the relay terminal 77A at a position away from the housing 51 ensures thermal effects of the temperature-controlled furnace 50A on the relay terminal 77A are reduced as much as possible.

### Technical Ideas and Effects

The technical ideas and effects of the present disclosure described in the above embodiments will be described below.

A first aspect of the present disclosure is a cable connecting method of connecting the heater 52 and the conductive cable 76 configured to supply a power to the heater 52, the heater 52 being provided in the thermal processing apparatus 1 and including the heater body 52a and the terminal (the busbar 72) conductive to the heater body 52a. The cable connecting method includes: (A) providing the connecting member 73 configured to connect the terminal and the conductive cable 76; (B) joining the first portion (the plate 74) of the connecting member 73 and the terminal through welding, the first portion being formed of a material the same as a material of the terminal; and (C) linking the second portion (the sleeve 75) of the connecting member 73 and the conductive cable 76 through caulking, the second portion being formed of a material different from the material of the first portion.

According to the above, the cable connecting method connects the terminal (the busbar 72) and the conductive cable 76 via the connecting member 73, thereby omitting bolting requiring torque management, reducing a risk of burnout during installation, and eliminating a need to fasten bolts during operation. That is, the connecting member 73 enables stable connection of the conductive cable 76. Also, the connecting member 73 has a simple structure of the first portion (the plate 74) and the second portion (the sleeve 75), and thus it is possible to reduce a production cost and facilitate a task of connection. Further, the connecting member 73 can increase the degree of freedom of a connecting position of the conductive cable 76 by adjusting the length of the first portion or the like.

In (C), caulking of the second portion is performed in a state in which the conductive cable 76 is inserted into the interior of the second portion (the sleeve 75) having plasticity higher than the first portion (the plate 74) and formed in a hollow cylindrical shape. Thus, the cable connecting method forms the caulked portion 75c at the second portion, and can firmly link the conductive cable 76 to the connecting member 73.

In (B), the surface of the first portion (the plate 74) formed in a flat-plate shape is welded to the surface of the terminal (the busbar 72) formed in the flat-plate shape. Thus, the cable connecting method can firmly link the first portion of the connecting member 73 and the terminal of the heater 52.

The cable connecting method is performed in the order of (A), (B), and (C) in sequence. Thus, the cable connecting method performs linking of the conductive cable 76 after welding between the terminal and the connecting member 73, and thus can suppress misalignment or the like of the connecting member 73 relative to the terminal.

The material of the terminal (the busbar 72) and the material of the first portion (the plate 74) are: iron, chromium, aluminum, tungsten, cobalt, or nickel; or an alloy containing at least one of iron, chromium, aluminum, tungsten, cobalt, or nickel as a main component. Thus, the terminal and the first portion have sufficient rigidity and conductivity, and can adhere to each other with a strong welding force.

The material of the second portion (the sleeve 75) is copper or an alloy containing copper as a main component. Thus, the second portion can have plasticity enough to maintain the linking of the conductive cable 76, while being electrically conductive to the conductive cable 76.

A second aspect of the present disclosure is a production method of the connecting member 73 configured to connect the heater 52 and the conductive cable 76 configured to supply a power to the heater 52, the heater 52 being provided in the thermal processing apparatus 1 and including the heater body 52a and the terminal (the busbar 72) conductive to the heater body 52a. The production method of the connecting member 73 includes: (A) providing the first metal member 74A that forms the first portion (the plate 74) of the connecting member 73 and is formed of a material the same as a material of the terminal, and the second metal member 75A that forms the second portion (the sleeve 75) of the connecting member 73 and is formed of a material different from the material of the first portion; (B) joining the first metal member 74A and the second metal member 75A through friction welding, thereby forming the precursor (the first precursor 73A); and (C) cutting the precursor, thereby forming the second portion that is linkable to the conductive cable 76. The connecting member 73 produced by this production method enables stable connection of the conductive cable 76, and reduction in cost.

Further, in (A), the first metal member 74A having a flat-plate shape and the second metal member 75A having a rod shape are provided. Thus, the production method can readily form the shapes of the first portion (the plate 74) and the second portion (the sleeve 75), which are subsequently formed.

In (C), sleeve processing is performed on the second metal member 75A having the rod shape that is joined to the first metal member 74A, thereby forming the second portion (the sleeve 75) having a hollow cylindrical shape. Thus, the production method can form the hollow cylindrical second portion that is linkable to the conductive cable 76, while suppressing joint failure between the first portion and the second portion.

The material of the terminal (the busbar 72) and the material of the first metal member 74A are: iron, chromium, aluminum, tungsten, cobalt, or nickel; or an alloy containing at least one of iron, chromium, aluminum, tungsten, cobalt, or nickel as a main component. Thus, the terminal and the first portion have sufficient rigidity and conductivity, and can adhere to each other with a strong welding force.

The material of the second metal member 75A is copper or an alloy containing copper as a main component. Thus, the second portion can have plasticity enough to maintain the linking of the conductive cable 76, while being electrically conductive to the conductive cable 76.

A third aspect of the present disclosure is the thermal processing apparatus 1 configured to process the plurality of substrates W. The thermal processing apparatus 1 includes: the process chamber 10 configured to house the plurality of substrates W; the temperature-controlled furnace 50 provided to cover the process chamber 10; the heater 52 that includes the heater body 52a provided in the interior of the temperature-controlled furnace 50, and the terminal (the busbar 72) conductive to the heater body 52a and projecting outward of the temperature-controlled furnace 50; the conductive cable 76 configured to supply a power to the heater body 52a; and the connecting member 73 configured to connect the terminal of the heater 52 and the conductive cable 76. The connecting member 73 includes the first portion (the plate 74) formed of a material the same as a material of the terminal, and the second portion (the sleeve 75) formed of a material different from the material of the first portion. The first portion and the second portion are joined together through friction welding. The welded portion 73w of the terminal and the first portion that are welded together is formed between the terminal and the first portion. The second portion includes the caulked portion 75c engaged with the conductive cable 76. In this case, the thermal processing apparatus 1 enables stable connection of the conductive cable 76, and reduction in cost.

The temperature-controlled furnace 50 includes the housing 51 configured to circulate a coolant near an outer circumferential surface of the temperature-controlled furnace 50, and the relay terminal 77 to which the conductive cable 76 is connected at the outer circumferential surface of the housing 51. The conductive cable 76 is arranged along the outer circumferential surface of the housing 51, and connected to the relay terminal 77. Thus, even if the conductive cable 76 receives thermal effects of heat of the temperature-controlled furnace 50, the conductive cable 76 is lowered in temperature at the outer circumferential surface of the housing 51, so that transfer of heat to the relay terminal 77 can be suppressed.

The material of the terminal (the busbar 72) and the material of the first portion (the plate 74) are: iron, chromium, aluminum, tungsten, cobalt, or nickel; or an alloy containing at least one of iron, chromium, aluminum, tungsten, cobalt, or nickel as a main component. Thus, the terminal and the first portion have sufficient rigidity and conductivity, and can adhere to each other with a strong welding force.

The material of the second portion (the sleeve 75) is copper or an alloy containing copper as a main component. Thus, the second portion can have plasticity enough to maintain the linking of the conductive cable 76, while being electrically conductive to the conductive cable 76.

The cable connecting method, the production method of the connecting member 73, and the thermal processing apparatus 1 according to the embodiments disclosed herein are exemplary in all respects and are not restrictive. The embodiments can be modified and improved in various forms without departing from the scope and intent of the attached claims. The matters described in the above embodiments can have other configurations in a scope in which there is no contradiction, and can be combined together in a scope in which there is no contradiction.

According to an embodiment, it is possible to achieve stable connection of a conductive cable, and reduction in cost.

What is claimed is:

1. A cable connecting method of connecting a heater and a conductive cable configured to supply a power to the heater, the heater being provided in a thermal processing apparatus and including a heater body and a terminal conductive to the heater body, the cable connecting method comprising:
(A) providing a connecting member configured to connect the terminal and the conductive cable;
(B) joining a first portion of the connecting member and the terminal through welding, the first portion being formed of a material same as a material of the terminal; and
(C) linking a second portion of the connecting member and the conductive cable through caulking, the second portion being formed of a material different from the material of the first portion.

2. The cable connecting method according to claim 1, wherein
in (C), caulking of the second portion is performed in a state in which the conductive cable is inserted into an interior of the second portion having plasticity higher than the first portion and formed in a hollow cylindrical shape.

3. The cable connecting method according to claim 1, wherein
in (B), a surface of the first portion formed in a flat-plate shape is welded to a surface of the terminal formed in a flat-plate shape.

4. The cable connecting method according to claim 1, wherein
(A), (B), and (C) are performed in an order of (A), (B), and (C) in sequence.

5. The cable connecting method according to claim 1, wherein
a material of the terminal and a material of the first portion are:
iron, chromium, aluminum, tungsten, cobalt, or nickel; or
an alloy containing at least one of iron, chromium, aluminum, tungsten, cobalt, or nickel as a main component.

6. The cable connecting method according to claim 1, wherein
a material of the second portion is copper or an alloy containing copper as a main component.

7. A production method of a connecting member configured to connect a heater and a conductive cable configured to supply a power to the heater, the heater being provided in a thermal processing apparatus and including a heater body and a terminal conductive to the heater body, the production method of the connecting member comprising:
(A) providing
a first metal member that forms a first portion of the connecting member and is formed of a material same as a material of the terminal, and
a second metal member that forms a second portion of the connecting member and is formed of a material different from the material of the first portion;
(B) joining the first metal member and the second metal member through friction welding, thereby forming a precursor; and
(C) cutting the precursor, thereby forming the second portion that is linkable to the conductive cable.

8. The production method of the connecting member according to claim 7, wherein
in (A), the first metal member having a flat-plate shape and the second metal member having a rod shape are provided.

9. The production method of the connecting member according to claim 8, wherein
in (C), sleeve processing is performed on the second metal member having the rod shape that is joined to the first metal member, thereby forming the second portion having a hollow cylindrical shape.

10. The production method of the connecting member according to claim 7, wherein
a material of the terminal and a material of the first metal member are:
iron, chromium, aluminum, tungsten, cobalt, or nickel; or
an alloy containing at least one of iron, chromium, aluminum, tungsten, cobalt, or nickel as a main component.

11. The production method of the connecting member according to claim 7, wherein
a material of the second metal member is copper or an alloy containing copper as a main component.

12. A thermal processing apparatus configured to process a plurality of substrates, the thermal processing apparatus comprising:
a process chamber configured to house the plurality of substrates;
a temperature-controlled furnace provided to cover the process chamber;
a heater that includes a heater body provided in an interior of the temperature-controlled furnace, and a terminal conductive to the heater body and projecting outward of the temperature-controlled furnace;
a conductive cable configured to supply a power to the heater body; and
a connecting member configured to connect the terminal of the heater and the conductive cable, wherein
the connecting member includes
a first portion formed of a material same as a material of the terminal, and
a second portion formed of a material different from the material of the first portion, and
the first portion and the second portion are joined together through friction welding,
a welded portion of the terminal and the first portion that are welded together is formed between the terminal and the first portion, and
the second portion includes a caulked portion engaged with the conductive cable.

13. The thermal processing apparatus according to claim 12, wherein
the temperature-controlled furnace includes
a housing configured to circulate a coolant near an outer circumferential surface of the housing, and
a relay terminal to which the conductive cable is connected at an outer circumferential surface of the housing, wherein
the conductive cable is arranged along the outer circumferential surface of the housing, and connected to the relay terminal.

14. The thermal processing apparatus according to claim 12, wherein
a material of the terminal and a material of the first portion are:
iron, chromium, aluminum, tungsten, cobalt, or nickel; or
an alloy containing at least one of iron,
chromium, aluminum, tungsten, cobalt, or nickel as a main component.

15. The thermal processing apparatus according to claim 12, wherein
a material of the second portion is copper or an alloy containing copper as a main component.
